(19) United States
(12) Patent Application Publication
(10) Pub. No.: US 2006/0040054 A1
(43) Pub. Date: Feb. 23, 2006

(54) Passivating ALD reactor chamber internal surfaces to prevent residue buildup

(76) Inventors: Ronald Martin Pearlstein, Macungie, PA (US); Bing Ji, Allentown, PA (US); Stephen Andrew Motika, Kutztown, PA (US)

Correspondence Address: AIR PRODUCTS AND CHEMICALS, INC.;PATENT DEPARTMENT, 7201 HAMILTON BOULEVARD, ALLENTOWN, PA, 181951501, US

(21) Appl. No.: 10/920,541

(22) Filed: Aug. 18, 2004

(51) Int. Cl. C23C 16/00

(52) U.S. Cl. 427/248.1; 118/715

(57) ABSTRACT

This invention is directed to an improved method for preventing deposition residue buildup on the internal surfaces of an ALD reactor chamber. In an ALD deposition process, the surfaces of a substrate are treated with an initiating precursor generating a labile atom reactive with a deposition precursor. Excess initiating precursor is removed from the reactor and the substrate surface then is exposed to a deposition precursor reactive with the labile atom under conditions for generating a fugitive reaction product containing the labile atom and leaving a deposition product. The process is repeated generating alternate layers of initiation and deposition precursor reaction products. The improvement in the ALD process resides in passivating the internal surfaces of the reactor by removing labile atoms reactable with either the initiating or deposition precursors prior to effecting ALD deposition.

### BACKGROUND OF THE INVENTION

Atomic Layer Deposition (ALD) is recognized as a deposition technique that forms high quality materials with minimal defects and tight statistical process control. ALD includes exposing an initial substrate to a first chemical precursor to accomplish chemisorption of the precursor onto the substrate thereby forming a deposition layer. Then, any excess of the first precursor is purged from over the reactor and from the substrate. Next, the deposition layer formed by the first chemical precursor is contacted with a second initiation precursor often different from the first initiation precursor and, a second deposition layer is formed over the substrate. Any excess of the second precursor is purged from the reactor and the steps are repeated until the desired deposition product is obtained.

A problem associated with ALD is that there can be unwanted deposition of the first and second precursors on the internal surfaces and internal components of the ALD reactor. These unwanted deposits not only can alter the deposition chemistry by creating process drift such that the properties (including intrinsic film properties such as chemical composition, density, internal stress, contamination as well as extrinsic properties such as film thickness) of the coating vary over time. Then too, because the precursors react with sites on the ALD reactor surfaces, deposition layer films build on the internal reactor surfaces over time. Once a critical thickness of undesired deposit layers accumulates, there is a tendency for the undesired coating to release as particles or flakes and these particles or flakes then contaminate the desired substrate.

To prevent contamination due to particle release and flaking, ALD reaction chambers must be cleaned from time to time. Cleaning adds to the cost of ownership not only because of the cost of cleaning chemicals and related pollution abatement equipment, but also because it reduces the uptime of the expensive equipment, and thus leads to lost production. Therefore, it is desired that one reduce build up or deposition products on the internal surfaces of the ALD reactor and thereby reduce the frequency of chamber cleaning.

The following references are directed to ALD processes:

U.S. Pat. No. 6,627,260 discloses an ALD deposition method for the prevention of intolerable defects in products which includes providing a uniform initiation layer over all regions in the ALD reactor by contacting a substrate with a first initiation precursor and forming a first portion of an initiation layer on the substrate. Then, a part of the substrate is contacted with a deposition precursor different from the first initiation precursor and a second deposition layer is generated. Suggested examples of initiation precursors include trimethylaluminum, water, H₂O₂, CH₃OH and the like which generate reactive OH sites. Other examples of initiation precursors include SiH₄ and SiCl₄ and deposition precursors include chlorosilanes, e.g., SiH₃Cl, SiH₂Cl₂, SiHCl₃ and methylsilanes such as Si(CH₃)ₙH₄₋ₙ which react with the OH or Cl sites generated by the initiation precursor.

U.S. Pat. No. 6,720,259 discloses a passivation method for improving the uniformity and repeatability of Atomic Layer Deposition (ALD) reactors, and more generally chemical vapor deposition (CVD) reactors, particularly cold wall and warm wall reactors by reconditioning the internal surfaces in order to reduce condensation of ALD precursors and parasitic deposition. The passivating layer is deposited as a non-reactive coating to the precursor used to form a second coating on the reactor surfaces. Such passivation with a nonreactive coating prevents parasitic deposition from occurring by remnants of precursor chemicals used to deposit films on the substrate. In the deposition of ZrO₂ and HfO₂ as film layers on a substrate, for example, Al₂O₃ is first deposited using an ALD process employing alternating pulses of trimethylaluminum and water as a nonreactive coating on the interior of an ALD reactor chamber, shower heads and the like. Then, deposition of ZrO₂ or HfO₂ is effected by alternating ZrCl₄ and H₂O precursor pulses in the reactor. The wafer is removed and the reactor conditioned again with another treatment of trimethylaluminum and water forming Al₂O₃. Multiple layers of Al₂O₃ films are formed by repeating the ALD cycles many times, e.g., 30 to 60 times in order to achieve reconditioning between deposition processing.

### BRIEF SUMMARY OF THE INVENTION

This invention is directed to an improved method for preventing deposition residue buildup on the internal surfaces of an ALD reactor chamber. In an ALD deposition process, the surfaces of a substrate are treated with an initiating precursor generating a labile atom reactive with a deposition precursor. Excess initiating precursor is removed from the reactor and the substrate surface exposed to a deposition precursor which is reactive with the labile atom under the ALD operating. The reaction generates a fugitive reaction product containing the labile atom leaving a deposition layer. The process is repeated generating alternate layers of initiation and deposition precursor reaction product layers. The improvement in the ALD process described herein resides in passivating the internal surfaces and internal components of the ALD reactor by removing labile atoms therefrom which are reactable with either the initiating or deposition precursors under the ALD operating conditions employed for effecting ALD deposition prior to ALD deposition.

Significant advantages can be achieved by the ALD process and these include:
an ability to reduce accumulation of precursor deposits on the ALD reactor chamber walls that can affect the intrinsic or extrinsic film properties for the desired film on the substrate;
an ability to reduce spalling and particle shedding from ALD chamber walls;
an ability to decrease the need for chamber cleaning with its accompanying down-time and environmental, worker health and safety risks;
an ability to reduce the risk of fouling of downstream exhaust piping; and,
an ability to use less of the precursor chemicals for reasons of minimizing undesired chemisorption on reactor walls.

### BRIEF DESCRIPTION OF THE DRAWING

FIG. 1 is a reaction schematic of a prior art passivation process using trimethylaluminum as the passivation agent followed by ALD deposition using ZrCl₄.

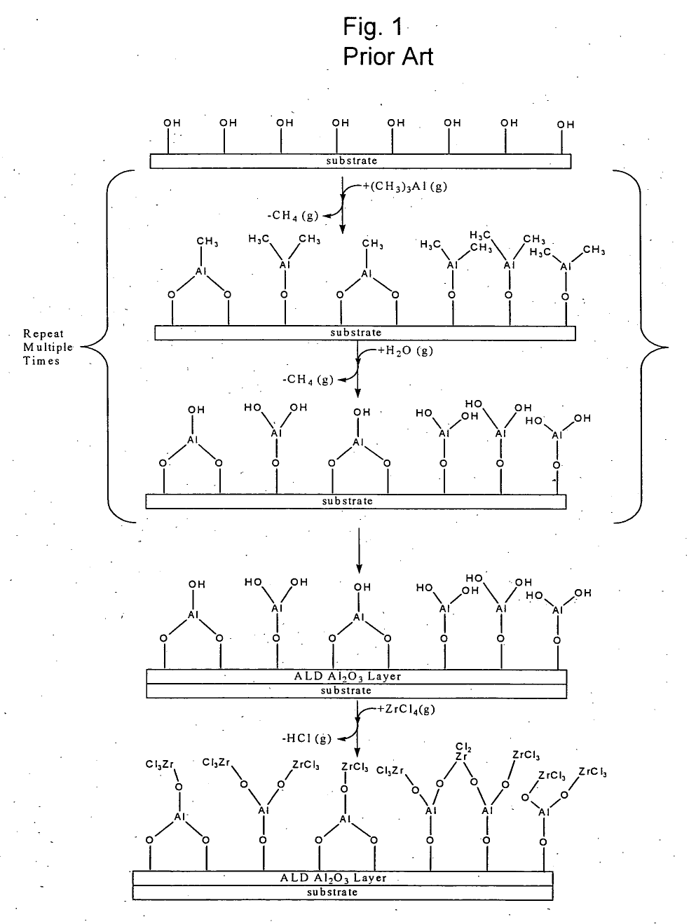

FIG. 2 is a reaction schematic of the passivation process for preventing the build up of deposition products on the internal surfaces of an ALD reaction chamber.

### DETAILED DESCRIPTION OF THE INVENTION

Atomic layer deposition (ALD) has been described as involving the formation of successive atomic layers on a substrate such as a semiconductor substrate. Such layers may comprise an epitaxial, polycrystalline, amorphous, etc. material. ALD may also be referred to as atomic layer epitaxy, atomic layer processing, etc. The deposition methods are often described in the context of formation of atomic layers on a semiconductor wafer. However, ALD deposition can be employed in the processing of a variety of substrates other than semiconductor substrates.

ALD has been described as a self-limiting process, in that a finite number of sites exist on a substrate to which a first precursor specie may form chemical bonds. Once all of the finite number of sites on the substrate are bonded with the first specie, the first specie will not bond to itself and thereby stack or form layers. When a second specie, i.e., a second precursor is utilized for deposition, it too will only bond to the first specie. The second precursor employed may be reactive with a site on the first specie but, once reacted will not react with itself. It too becomes self-limiting. However, process conditions can be varied in some ALD processes to render the ALD process non self-limiting. In those process schemes, the ALD process utilizes a specie or precursor which forms more than one monolayer at a time. In view of these process capabilities, ALD. offers a variety of advantages and improvements over other methods of forming deposition materials on a substrate.

In a common ALD process, the labile atom generated by the first or initiation precursor on the substrate surface is H which is derived from an OH or NH group. The second precursor, e.g., a metal halide that is reactive with the labile atom generated by the first precursor species reacts with the labile H atom generating fugitive halogen halide leaving an M—O— or M—N bond with the surface.

The causation of build up on internal surfaces of the ALD reactor results from the fact that OH and NH sites are generated on the internal surface of the ALD reactor through contact with atmospheric moisture or on treatment with the initiation precursors employed in ALD processes. As a result the internal surface of the ALD reactor becomes reactive with the second precursor and metal deposition films or products are subsequently formed on the internal surfaces. With each ALD processing step, alternating layers of deposition products are formed on the ALD reactor surface whereas perhaps only one or a few layers are formed on the desired semiconductor substrate.

In an embodiment of the improved ALD process described herein the surfaces are passivated to make the surfaces hydrophobic and non-reactive with either the initiation or secondary precursor. By that it is meant that the internal surface sites capable of forming terminal OH or NH groups are passivated by reacting such sites with a compound capable of rendering the surface hydrophobic and relatively hydrolytically stable under the ALD deposition conditions employed. As a result, OH— or NH— containing functionality cannot be formed on the ALD reactor surfaces on exposure to the atmosphere during any portion of the ALD process, and thus the deposition of metals and residue can be reduced and possibly avoided.

To render the internal surfaces of the ALD reactor hydrophobic and hydrolytically stable, the OH or NH activated surfaces are contacted with a gas, mist or vapor containing a reactive compound described by the formulas:
RₐEX_{b}Y_{c}Z_{d} Formula 1
and
AₙMXₚY_{q} Formula 2
wherein in formula 1 R is any combination of hydrolytically-resistant functional groups, devoid of free OH or NH functional groups; E is a metal or metalloid element from periodic groups 4 and 14 including Si, Ge, Sn, Ti, Zr and Hf; X, Y, and Z are labile groups where the subscript a ranges from 1 to 3 (preferably 3), the value of b, c, and d can each independently range from 0-3 with the requirement being that the sum of b+c+d should equal 4-a and hence the sum of b+c+d ranges from 1-3, preferably 1 or 2 and most preferably 1.

With respect to formula 1, examples of a functional group that can comprise R include C₁₋₁₈ alkyl, preferably C₁₋₄ alkyl, aryl, alkaryl, C₃₋₂₀ alkyl carboxylates and esters, alkyl or aryl or alkaryl mercaptides, glycolates and other chelates. Examples of functional groups that can comprise X, Y or Z include halogen atoms (Cl, Br, I, F), hydrogen, alkoxides, amines (NHR′, where R′ may be hydrogen, an organic group or an organometallic group such as an organosilane).

In the compounds represented by formula 2, M represents an element from periodic group 13 (e.g., B, Al, Ga). A functional group that can comprise A include C₃₋₁₈ alkyl, preferably C₄₋₉ alkyl, aryl, alkaryl, C₃₋₂₀ alkyl carboxylates or esters, alkyl or aryl or alkaryl mercaptides, glycolates and other chelates. The large bulky alkyl groups offer greater resistance to hydrolysis than do the small methyl groups which may be used in the compounds of formula 1. Examples of functional groups that can comprise X, Y or Z include halogen atoms (Cl, Br, I, F), hydrogen, alkoxides, amines (NHR′, where R′ may be hydrogen, an organic group or an organometallic group such as an organosilane). The subscript n is either 1 or 2 (preferably 2), the value of p, and q can each independently range from 0-2 with the requirement being that the sum of p+q should equal 3−n (and hence the sum of p+q ranges from 1-2, most preferably 1) and n+p+q=3.

As can be noted from the formulas, the reactants have a limited number (preferably only one) labile group that will react with a surface hydroxyl or NH group initially present on the chamber wall and thereby block further reaction with either the first or the second precursor, e.g., a metal halide such as Hf, Zr, or Al halide, metal amide, water, amine or the like. Where there is an increase in labile groups reactable with OH or NH, i.e., where the sum of b+c+d is 2 or 3 or the sum of p+q is 2, there is the possibility that a site can be generated that is reactable with either the initiation or second precursor, but for purposes of this invention, the probability of providing sufficient reactive sites for establishing significant buildup on the internal reactor surfaces and interior components is quite low and, therefore, deemed negligible.

Specific illustrative examples of compounds represented by formula 1 which of applied as a gas, mist or vapor include: chlorotrimethylsilane (CH₃)₃SiCl [R=CH₃; X=Cl; a=3, b=1, c=d=0]; bromooctyldimethylsilane (C₈H₁₇)(CH₃)₂SiBr [R=CH₃ and n-C₈H₁₇; X=Br; a=3, b=1, c=d=0]; hexamethydisilazane (CH₃)₃SiNHSi(CH₃)₃ [R=CH₃; X=NHSi(CH₃)₃; a=3, b=1, c=d=0] 2-propanolatotris(isooctadecanoato)titanium(IV) a.k.a. Ken-React TTS® Ti(OC₃H₇)(OC(O)C₁₇H₃₅)₃ [R=C₁₇H₃₅CO₂, X=C₃H₇O; a=3, b=1, c=d=0]. The compound can be applied as a gas or vapor as pure species or they can be present as a mixture of such compounds with or without some other carrier such as nitrogen, helium, argon, carbon dioxide or the like. Compounds represented by formula 2 include (ⁱC₄H₉)₂AlCl (diisobutylaluminum chloride) where R=ⁱC₄H₉, M=Al, n=2, p=1, q=0, X=Cl and Kenrich KA301 (diisobutoxy(oleyl)acetoacetyl aluminate) where R=C₁₈H₃₇OC(O)CHC(O)CH₃, M=Al, n=1, p=2, q=0, X=ⁱC₄H₉O.

Passivation of the ALD internal reactor surfaces is effected by contacting the internal surfaces or internal components of the ALD reactor at a pressure generally ranging from about 0.001 bar to a pressure of about 1 bar. The temperature can range from around ambient or just below ambient to about 500° C. The exposure time can range from about 1 second to about 4 hours, with an exposure time ranging from about 1 second to about 5 minutes preferred. Following the treatment, unreacted (excess) passivation chemical may be purged from the chamber by application of vacuum or the flow of a non-reactive gas such as nitrogen, helium, argon, carbon dioxide, or the like or a combination of evacuation and gas purge.

Once the chamber internal surfaces have been passivated with these hydrophobic and relatively hydrolytically stable functional groups, OH- or NH-containing functionality cannot be formed by the continued ALD process or by subsequent hydrolysis or ammonolysis reactions. Thus, after the reactor internal surfaces have been passivated, the reactor is ready to commence the ALD processes.

In a preferred embodiment of the process, the ALD reaction chamber is accorded a pre-treatment to ensure that all of the incipient reactive sites on the ALD chamber surfaces are activated prior to effecting passivation of these reactive sites. By ensuring that most of the reactive sites are activated prior to effecting passivation, passivation becomes more effective and there is less likelihood of deposition buildup. Thus, the precursors are prevented from being deposited on the internal surfaces of the ALD reactor.

The usefulness of the compounds of formula 1 and formula 2 is directly related to the proposed ALD processing conditions for effecting deposition of the initiating or secondary precursor employed in the ALD deposition process. The compounds of formula 1, in general, are more resistant to hydrolysis than are those in formula 2. As a result the compounds of formula 1 may be used with a wider range of precursors which may be deposited at higher temperatures. For example, a passivation layer employing trimethylchlorosilane as the passivation agent, may be used in the high temperature processing (>325° C.) of hafnium and zirconium films whereas an aluminum based passivation agent represented by formula 2 may hydrolyze at temperatures <325° C. The initiation and secondary precursors have to be selected such that their ALD deposition temperatures are below the hydrolysis temperature of the passivating layer. To illustrate the point, reference is made to the use of trimethylaluminum in ALD deposition. These surfaces hydrolyze at temperatures of <325° C. which are often employed for hafnium and zirconium ALD deposition.

The exemplary compounds of formulas 1 and 2 may be used with initiation and secondary precursors such as water, methanol, hydrogen peroxide, and tetrachlorides of zirconium, hafnium and silicon, trialkylaluminum, e.g. trimethylaluminum. However, as mentioned the compounds of formula 2 often require the use of precursors which have lower deposition temperatures than do the tetrachlorides of zirconium or hafnium.

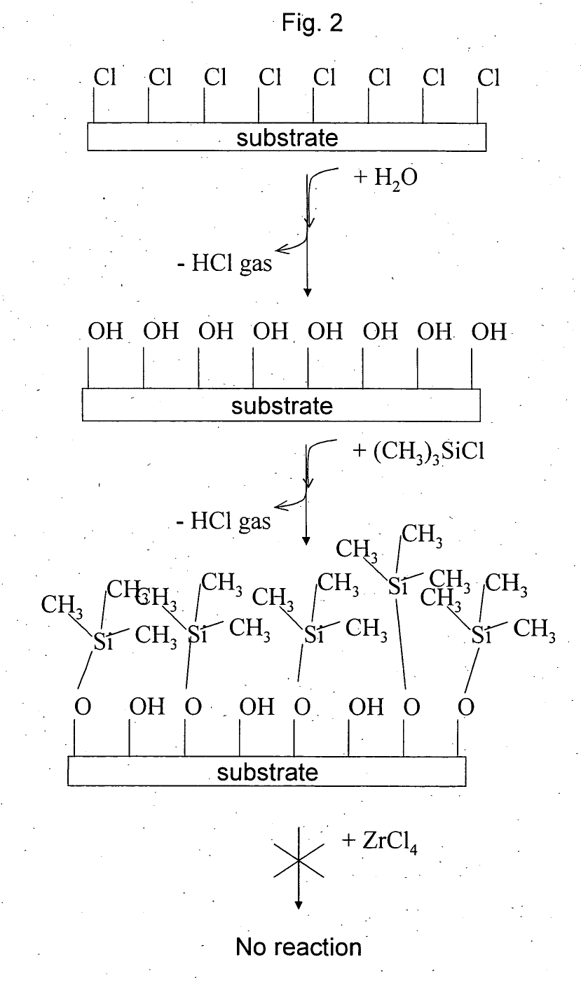

To facilitate an understanding of a preferred method for passivating the internal surfaces of the ALD reactor, reference is made to the FIG. 2. The following process steps are used:

1. An ALD reactor wall 2 has a surface 4 that is cleaned prior to ALD deposition production and preferably prior to surface passivation. For example, in the embodiment shown, a plurality of reactive Cl sites 6 are formed by a conventional ALD cleaning process, and thus, the reactive cleaning species is conveyed to the interior surfaces of the ALD reactor. If water was used as the cleaning agent, then OH groups would have been generated. Cleaning of the surface may be accomplished by other methods, e.g., mechanical scrubbing or by immersion in a suitable etch or cleaning bath of solvents, acids, alkalis or water.

2. Once reactive sites 6 are formed on the interior surface of the ALD reactor wall 2, the interior surfaces 4 of the ALD reactor are subjected to activation, i.e., treatment for the purpose of converting the reactive cleaning species to sites having a labile atom, if other than labile. In the embodiment shown, water is contacted with the newly chlorine cleaned ALD reactor for the purpose of generating reactive OH sites and fugitive HCl. Activation also can be effected by contacting with oxygen (alone or in combination with hydrogen gas), hydrogen peroxide, ozone, or air. Activation can take place at or slightly below ambient temperature or can be accomplished more rapidly at elevated temperatures, preferably below 500° C.

3. Passivation of the ALD reactor surfaces is effected by rendering the interior surface hydrophobic and hydrolytically stable. The embodiment shown reacts the OH reactive sites with trimethylchlorosilane eliminating HCL and leaving a trimethylsiloxane group. Because trimethylchlorosilane has only one labile atom, i.e., one chlorine atom, a bulky group, i.e., trimethylsiloxy is left on the surface. That group is resistant to hydrolysis and thus the surface of the ALD reactor wall 2 is rendered hydrolytically stable. Should dimethyldichlorosilane be the reactant of choice, there are two reactive, labile groups. In some cases the labile groups bridge and react with two of the reactive sites on the surface 4. However, in some cases, the second labile atom may not react with a reactive site 6 on surface 4 and thus the remaining Cl atom may be exposed for reaction with the second deposition precursor. Thus, there may be segments where there is the possibility of a build up on the surface 4.

As illustrated in FIG. 2, not every active site needs to react with the passivating agent in order to achieve the desired effect as long as a significant portion of the surface 4 is inhibited from further reaction. The process is self-limiting in that once a monolayer of the passivation film encloses the ALD reactor chamber surface, no further chemisorption reaction will occur, and no further growth of the passivating film will occur even if the cycle is repeated.

The above described process may be varied by using ammonia (NH₃), a primary or secondary amine, amide etc. for the purpose of generating reactive NH sites and fugitive HCl on surface 4. Passivation of the surface can be effected by reaction with trimethylchlorosilane.

In summary, following the passivation procedure, the ALD process can be commenced by placing substrates in the reactor chamber in the usual manner. The internal surfaces of the treated ALD reactor will differ from that of the substrate in that its surfaces are now coated with species that are not reactive with either of the ALD precursors or offer reactive sites when contacted with atmospheric oxygen.

Eventually the surface functionalization of the present invention might become damaged and patches of ALD deposition might begin to form after a plurality of substrates are processed. It may therefore be necessary to occasionally re-apply the treatment as described above either with or without stripping or cleaning the pre-existing surface. This re-application may be applied as a preventive maintenance procedure before any evidence of loss in ALD deposition selectivity is observed. It may be possible to patch or re-apply subsequent system passivation treatments by using less extreme or less time-consuming conditions thereby saving time in subsequent applications.

In contrast to the passivation process described in U.S. Pat. No. 6,720,259, only a single passivation step is required to prevent deposition buildup on the internal surfaces of the ALD reactor. Alternating layers are not required nor can alternating passivation layers be formed because of the self limiting passivation process.

1. An improved method for preventing deposition residue buildup on the internal surface of an ALD reactor chamber which comprises:
passivating the internal surface of the ALD reactor chamber by removing labile atoms reactable on the internal surface of the ALD reactor chamber with a precursor employed in the ALD deposition process at the ALD deposition temperature prior to effecting ALD deposition.

2. The method of claim 1 wherein the labile atom is H.

3. The method of claim 2 wherein the labile atom is H and is pendent from oxygen in the form of an OH group or pendent from a nitrogen atom in the form of an NH group.

4. The method of claim 3 wherein passivation of the OH groups by removal of the labile H atom is effected by reaction with a compound represented by the formulas:
RₐEX_{b}Y_{c}Z_{d} Formula 1
and
AₙMXₚY_{q} Formula 2
wherein in formula 1 R is any combination of hydrolytically-resistant functional groups, devoid of free OH or NH functional groups; E is a metal or metalloid element from periodic groups 4 and 14 and X, Y, and Z are labile groups where the subscript a ranges from 1 to 3; with the requirement the sum of b+c+d ranges from 1 to 3 provided the sum of a+b+c+d is 4;
and in the compounds represented by formula 2, M represents an element from periodic group 13, the functional group A comprises C₃₋₁₈alkyl, aryl, alkaryl, C₃₋₂₀ alkyl carboxylates or esters, alkyl or aryl or alkaryl mercaptides, glycolates and other chelates, X, Y and Z represent halogen atoms, hydrogen, alkoxides, NHR′, where R′ is hydrogen, an organic group or an organometallic group, the subscript n is either 1 or 2, the value of p, and q can each independently range from 0-2 with the requirement being that the sum of p+q should equal 3−n and hence the sum of p+q ranges from 1-2.

5. In a method for preventing deposition residue buildup on the internal surface of an ALD reactor chamber by applying a passivating film on the internal surface of said ALD reactor chamber which comprises:
passivating the internal surface of the ALD reactor chamber by reacting labile hydrogen atoms on the internal surface of the ALD reactor chamber with a compound represented by the formula:
RₐEX_{b}Y_{c}Z_{d}
wherein R represents C₁₋₈alkyl, aryl, alkaryl, C₃₋₂₀alkyl carboxylates and esters, alkyl or aryl or alkaryl mercaptides, glycolates and chelates, E is a metal or metalloid element from periodic groups 4 and 14, X, Y and Z represent halogen atoms hydrogen, alkoxides, amine or an organometallic group groups, the subscript a is 2 or 3, the value of b, c, and d can each independently range from 0-3 with the requirement the sum of b+c+d ranges from 1 to 2 provided the sum of a+b+c+d is 4.

6. The method of claim 5 wherein M is selected from the group consisting of Si, Ge, Sn, Ti, Zr and Hf;

7. The method of claim 6 wherein the sum of b+c+d is 1.

8. The method of claim 7 wherein M is silicon, X, Y and Z are Cl or Br and R is C₁₋₈ alkyl.

9. The method of claim 5 wherein the compound of formula 1 is chlorotrimethylsilane, bromooctyldimethylsilane, hexamethydisilazane, propanolatotris(isooctadecanoato)titanium(IV).

10. In a method for preventing deposition residue buildup on the internal surface of an ALD reactor chamber by applying a passivating film on the internal surface of said ALD reactor chamber which comprises:
passivating the internal surface of the ALD reactor chamber by reacting labile hydrogen atoms on the internal surface of the ALD reactor chamber with a compound represented by the formula:
AₙMXₚY_{q}
wherein M represents B, Al, or Ga, the subscript n is either 1 or 2, A is C₄₋₉ alkyl, aryl, alkaryl, or a C₃₋₂₀ alkyl carboxylates or ester, X, Y or Z are Cl, Br, I, or F, hydrogen, alkoxides, amines and the value of p and q is independently from 0-2 with the requirement being that the sum of p+q should equal 3−n and hence the sum of p+q ranges from 1-2.

11. The method of claim 10 wherein the sum of p+q is 1.

12. The method of claim 11 wherein the compound of formula 2 is selected from the group consisting of (ⁱC₄H₉)₂AlCl (diisobutylaluminum chloride) and (diisobutoxy(oleyl)acetoacetyl aluminate).

13. An ALD reactor chamber having an internal surface therein passivated with a plurality of sites of the formula:
surface-O—MRₐX_{b}Y_{c}Z_{d} or surface-N-MRₐX_{b}Y_{c}Z_{d}
wherein R represents C₁₋₈ alkyl, aryl, alkaryl, C₃₋₂₀ alkyl carboxylates and esters, alkyl or aryl or alkaryl mercaptides, glycolates and chelates, M is Si, Ge, Sn, Ti, Zr or Hf, X, Y and Z represent halogen atoms, the subscript a is 2 or 3, the value of b, c, and d can each independently range from 0-3, the sum of b+c+d is from 0 or 1, provided the sum of a+b+c+d is 4.

14. The ALD reaction chamber of claim 13 wherein R is C₁₋₄ alkyl

15. The ALD reaction chamber of claim 13 wherein the sum of b+c+d is 0.

16. In a method for the deposition of a metal film on a substrate by contacting said substrate with a metal precursor in an Atomic Layer Deposition (ALD) chamber under ALD deposition conditions, the improvement for preventing residue buildup on the internal surface of an ALD reactor chamber which comprises:
forming an internal surface having OH or NH labile sites on the internal surface of said ALD chamber;
passivating the internal surface of the ALD reactor chamber by reacting the labile sites on the internal surface of the ALD reactor chamber with a compound represented by the formula:
RₐEX_{b}Y_{c}Z_{d}
wherein R represents C₁₋₈ alkyl, aryl, alkaryl, C₃₋₂₀ alkyl carboxylates and esters, alkyl or aryl or alkaryl mercaptides, glycolates and chelates, E is a metal or metalloid element from periodic groups 4 and 14, X, Y and Z represent halogen atoms hydrogen, alkoxides, amine or an organometallic group groups, the subscript a is 3, the value of b, c, and d can each independently range from 0-3 with the requirement the sum of b+c+d ranges from 1 to 2 prior to forming said film.

17. The process of claim 16 wherein the metal film deposited is selected from the group consisting of Zr, Hf, Si, and Ti.

18. The process of claim 17 wherein the sum of b+c+d is 1.

19. The process of claim 18 wherein the X, Y, or Z is Cl or Br and M is Si.

20. The process of claim 17 wherein the compound reacted with the labile site is selected from the group consisting of chlorotrimethylsilane, bromooctyldimethylsilane, hexamethydisilazane and 2-propanolatotris(isooctadecanoato)titanium(IV).
